(19) United States
(12) Patent Application Publication
(10) Pub. No.: US 2008/0175293 A1
(43) Pub. Date: Jul. 24, 2008

(54) SEMICONDUCTOR LASER DEVICE

(75) Inventor: Akira Tanaka, Kitakyushu-Shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 12/013,557

(22) Filed: Jan. 14, 2008

(30) Foreign Application Priority Data
Jan. 16, 2007 (JP) 2007-006840

(51) Int. Cl. H01S 5/30

(52) U.S. Cl. 372/45.01

(57) ABSTRACT

To provide a semiconductor laser device capable of reducing the power consumption and enhancing the reliability. The semiconductor laser device includes: a crystal substrate; a first clad layer of a first conductivity type formed on the crystal substrate; a first light guide layer of the first conductivity type formed on the first clad layer; an active layer of a single or multiple quantum well structure formed on the first light guide layer; an overflow preventing layer of a second conductivity type formed on the active layer; a second light guide layer of the second conductivity type formed on the overflow preventing layer; and a second clad layer of the second conductivity type formed on the second light guide layer, wherein the carrier concentration of the second light guide layer is set to the carrier concentration or more of the second clad layer.

### CROSS REFERENCE TO RELATED APPLICATION

This application is based upon and claims the benefit of priority from prior Japanese Patent Application No. 2007-006840, filed on Jan. 16, 2007, the entire contents of which are incorporated herein by reference.

### BACKGROUND OF THE INVENTION

1. Field of the Invention

The present invention relates to a semiconductor laser device.

2. Background Art

A blue-violet semiconductor laser device having a laser oscillation wavelength of 400 nm band has been developed for use in a next-generation DVD (digital versatile disk) and the like. As the element structure of the blue-violet semiconductor laser device, there is, for example, a structure having a double hetero-junction formed by providing an InGaAlN (indium gallium aluminum nitrogen) based material on a GaN (gallium nitride) substrate. In the structure, an upper clad layer is formed into a ridge shape, both sides of the upper clad layer are covered with dielectric films, such as an SiO₂ film, and electrodes are respectively provided on the upper side of the ridge and on the lower side of the substrate.

### SUMMARY OF THE INVENTION

A semiconductor laser device according to an aspect of the present invention includes: a first clad layer of a first conductivity type; a first light guide layer of the first conductivity type formed on the first clad layer; an active layer of a single or multiple quantum well structure formed on the first light guide layer; an overflow preventing layer of a second conductivity type formed on the active layer; a second light guide layer of the second conductivity type formed on the overflow preventing layer; and a second clad layer of the second conductivity type formed on the second light guide layer, wherein the carrier concentration of the second light guide layer is set to the carrier concentration or more of the second clad layer.

### BRIEF DESCRIPTION OF THE DRAWINGS

FIG. 1 shows a sectional view representing a structure of a semiconductor laser device according to an embodiment of the present invention;

FIG. 2 shows a graph representing the change in current to optical output characteristics and the change in current to voltage characteristics, with respect to the effective acceptor concentration of a light guide layer;

FIG. 3 shows a graph representing the change in operating voltage at 30 mW with respect to the effective acceptor concentration of the light guide layer;

FIG. 4 shows a graph representing the change in operating voltage at 30 mW with respect to the effective acceptor concentration of the light guide layer (when the effective acceptor concentration of an overflow preventing layer is fixed); and

FIG. 5 shows a graph representing the change in operating voltage at 30 mW with respect to the effective acceptor concentration of the light guide layer (when the effective acceptor concentration of a clad layer is fixed).

### DESCRIPTION OF THE EMBODIMENTS

In the following, an embodiment according to the present invention will be described with reference to the accompanying drawings.

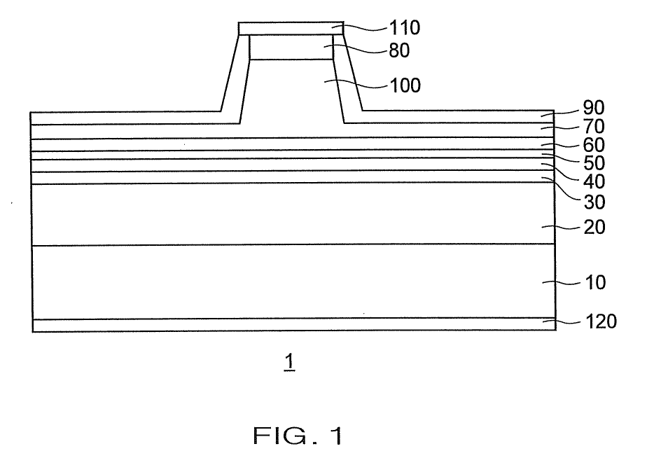

FIG. 1 shows a semiconductor laser device 1 according to an embodiment of the present invention. The semiconductor laser device 1 is constituted by successively forming, on an n-GaN substrate 10, an n-Al_{0.04}Ga_{0.96}N clad layer 20 (having a layer thickness of 0.5 to 2.0 μm, a donor concentration of 1 to 3×10¹⁸ cm⁻³), an n-GaN light guide layer 30 (having a layer thickness of 0.01 to 0.10 μm, a donor concentration of 1 to 3×10¹⁸ cm⁻³), an In_{0.13}Ga_{0.87}N (well layer)/In_{0.01}Ga_{0.99}N (barrier layer) MQW (Multiple Quantum Well) active layer 40 (having a well layer thickness of 2 to 5 nm, a well number of 2 to 4, a barrier layer thickness of 6 to 15 nm, and undoped), a GaN diffusion preventing layer (having a layer thickness of 0.01 to 0.10 μm, undoped, and not shown), a p⁺-Al_{0.2}Ga_{0.8}N overflow preventing layer 50 (having a layer thickness of 5 to 20 nm, and an effective acceptor concentration of 3×10¹⁸ cm⁻³), a p-GaN light guide layer 60 (having a layer thickness of 0.01 to 0.10 μm, and an effective acceptor concentration of 3×10¹⁸ cm⁻³), a p-Al_{0.04}Ga_{0.96}N clad layer 70 (having a layer thickness of 0.5 to 2.0 μm and an effective acceptor concentration of 2×10¹⁸ cm⁻³), and a p⁺-GaN contact layer 80 (having a layer thickness of 0.02 to 0.2 μm and an effective acceptor concentration of 5×10¹⁸ cm⁻³).

Note that the effective acceptor concentration means a concentration of an impurity (dopant) actually functioning as an acceptor. Meanwhile, in general, Si is used as an n-type impurity, and Mg is used as a p-type impurity. Generally, in a nitride based semiconductor, the activation rate of p-type impurities is low, and hence only several percent of doped Mg functions as the effective acceptor. For this reason, the p-type impurity is doped in the p-type semiconductor layer at a considerably high concentration of 1×10¹⁹ cm⁻³ to 1×10²¹ cm⁻³.

The GaN diffusion preventing layer (not shown) which is formed between the active layer 40 and the overflow preventing layer 50 is a layer for preventing the impurities from being diffused from p⁺-Al_{0.2}Ga_{0.8}N overflow preventing layer 50 to the active layer 40.

Further, in the semiconductor laser device 1, etching is performed to the p⁺-GaN contact layer 80 and to the middle of the p-Al_{0.04}Ga_{0.96}N clad layer 70, so that a stripe-like ridge type waveguide 100 is formed. Thereafter, an SiO₂ film 90 is formed on all the surfaces other than the surface above the ridge waveguide 100. Then, a p-side electrode 110 is formed above the ridge waveguide 100, and an n-side electrode 120 is formed on the lower surface of the n-GaN substrate 10.

A positive electrode of a DC power supply is connected to the p-type electrode 110, and a negative electrode of the DC power supply is connected to the n-type electrode 120, respectively. Thus, when a current is injected to the semiconductor laser device 1, many electrons are injected to the p side from the n-type layer, while many holes are also injected to the n side from the p-type layer. Then, the injected electrons and holes are recombined in the region of the active layer 40, so that light of a wavelength corresponding to the band gap of the material of the active layer 40 is emitted. The light emission efficiency is improved by forming the active layer 40 into a single or multiple quantum well structure. The overflow preventing layer 50 has a function to prevent the electrons injected to the active layer 40 from the lower n-type layer from overflowing to the upper p-type layer. Further, the light guide layers 30 and 60 confine the emitted light, so as to adjust the light density in the active layer 40. The clad layers 20 and 70 increase the electron density and the hole density in the active layer 40.

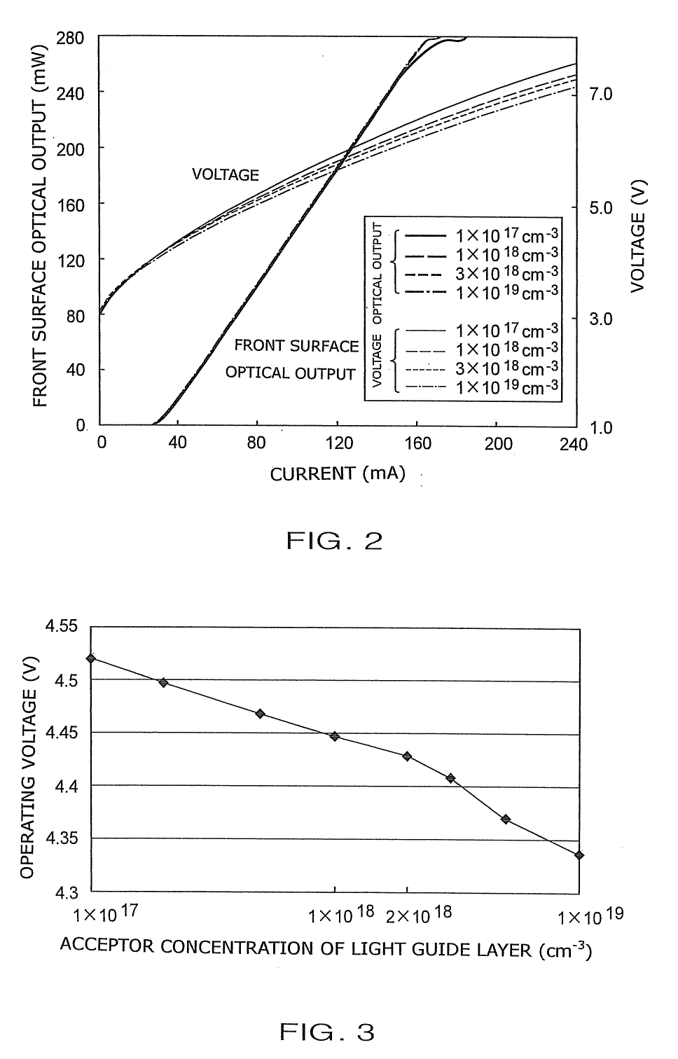

FIG. 2 shows results of a simulation of how optical output to injected current characteristics and voltage to injected current characteristics are changed in the case where the effective acceptor concentration of the light guide layer 60 is changed. In this case, even when the light guide layer 60 is undoped, Mg is diffused from the overflow preventing layer 50 and the clad layer 70, and hence the lower limit of effective acceptor concentration is set to 1×10¹⁷ cm⁻³ in the simulation.

As shown in FIG. 2, it can be seen that even when the effective acceptor concentration of the light guide layer 60 is changed, the optical output is hardly changed, but the voltage is lowered as the effective acceptor concentration is increased. Note that the effective acceptor concentration of the overflow preventive layer 50 is set to 3×10¹⁸ cm⁻³, and the effective acceptor concentration of the clad layer 70 is set to 2×10¹⁸ cm⁻³.

FIG. 3 shows a change in the operating voltage when the effective acceptor concentration of the light guide layer 60 is changed, and when the optical output is set to 30 mW. Here, the effective acceptor concentration of the overflow preventing layer 50 is set to 3×10¹⁸ cm⁻³, and the effective acceptor concentration of the clad layer 70 is set to 2×10¹⁸ cm⁻³.

As shown in FIG. 3, it can be seen that when the effective acceptor concentration of the light guide layer 60 is set to 2×10¹⁸ cm⁻³ or more of the effective acceptor concentration of the clad layer 70, the operating voltage is significantly lowered.

Therefore, the effective acceptor concentration of the light guide layer 60 is set to be higher than the effective acceptor concentration of the clad layer 70, so as to lower the resistance of the light guide layer 60. Thereby, it is possible to suppress that when the holes are injected from the side of the clad layer 70 into the light guide layer 60, the holes are collected in the light guide layer 60 to cause a voltage to be applied to the light guide layer 60. Note that the voltage suppressing effect is more significant as the thickness of the light guide layer 60 is increased.

On the other hand, even when the effective acceptor concentration of the light guide layer 60 is increased from 1×10¹⁷ cm⁻³ (undoped state), the height of a spike (barrier) formed in the interface between the light guide layer 60 and the overflow preventing layer 50 is not so increased, and hence the influence of the increase in the effective acceptor concentration of the light guide layer 60 is small.

In this case, by increasing the effective acceptor concentration of the overflow preventing layer 50, it is possible to enhance the overflow preventing effect and thereby increase the carrier contributing to the radiative recombination. Thus, the optical output is increased.

In order to reduce the spike, it is necessary to set the effective acceptor concentration of the overflow preventing layer 50 to be higher than at least the effective acceptor concentration of the light guide layer 60. This lowers the operating voltage so as to reduce the power consumption, thereby improving the reliability.

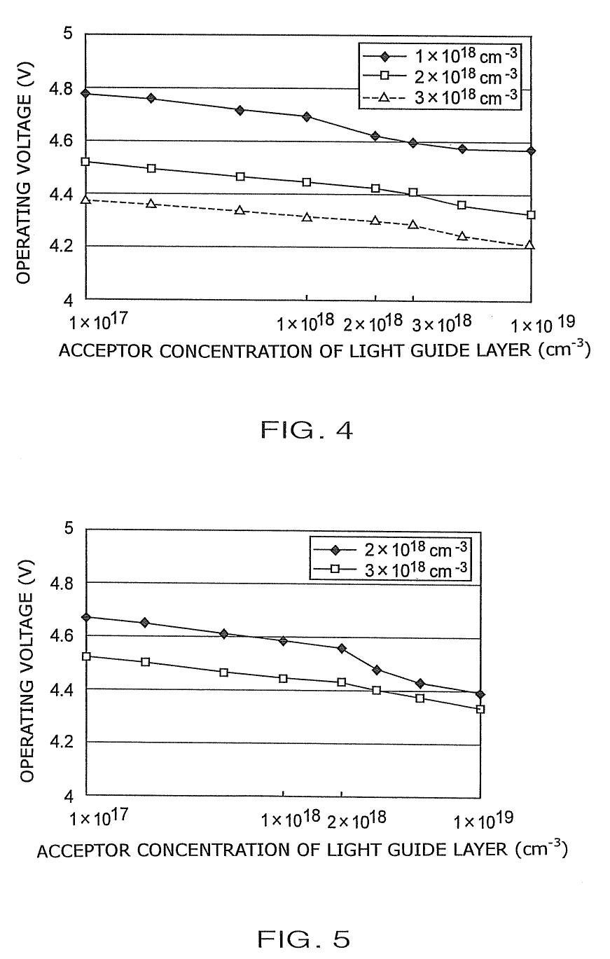

Note that here, FIG. 4 shows relations between the effective acceptor concentration of the light guide layer 60 and the operating voltage, in the respective cases where the effective acceptor concentration of the clad layer 70 is set to 1×10¹⁸ cm⁻³, 2×10¹⁸ cm⁻³, and 3×10¹⁸ cm⁻³ in the state that the effective acceptor concentration of the overflow preventing layer 50 is fixed to 3×10¹⁸ cm⁻³.

As shown in FIG. 4, it can be seen that when the effective acceptor concentration of the clad layer 70 is set to 1×10¹⁸ cm⁻³, and when the effective acceptor concentration of the light guide layer 60 is set to 1×10¹⁸ cm⁻³ or more of the effective acceptor concentration of the clad layer 70, the operating voltage is significantly lowered.

Further, it can be seen that when the effective acceptor concentration of the clad layer 70 is set to 2×10¹⁸ cm⁻³, and when the effective acceptor concentration of the light guide layer 60 is set to 2×10¹⁸ cm⁻³ or more of the effective acceptor concentration of the clad layer 70, the operating voltage is significantly lowered.

Further, it can be seen that when the effective acceptor concentration of the clad layer 70 is set to 3×10¹⁸ cm⁻³, and when the effective acceptor concentration of the light guide layer 60 is set to 3×10¹⁸ cm⁻³ or more of the effective acceptor concentration of the clad layer 70, the operating voltage is significantly lowered.

Here, FIG. 5 shows relations between the effective acceptor concentration of the light guide layer 60 and the operating voltage, in the respective cases where the effective acceptor concentration of the overflow preventive layer 50 is set to 2×10¹⁸ cm⁻³ and 3×10¹⁸ cm⁻³ in the state that the effective acceptor concentration of the clad layer 70 is fixed to 2×10¹⁸ cm⁻³.

As shown in FIG. 5, it can be seen that also in the case where the effective acceptor concentration of the overflow preventing layer 50 is set to any of 2×10¹⁸ cm⁻³ and 3×10¹⁸ cm⁻³, the operating voltage is significantly lowered when the effective acceptor concentration of the light guide layer 60 is set to 2×10¹⁸ cm⁻³ or more of the effective acceptor concentration of the clad layer 70.

Meanwhile, the overflow preventing layer 50 has a large band gap. Thus, the effective acceptor concentration of the overflow preventing layer 50 is set a little higher than the effective acceptor concentration of the active layer 40 and the light guide layer 60, to bring the quasi Fermi level close to the valence band, thereby reducing the height of the spike formed in the interface between the overflow preventing layer 50 and the light guide layer 60. This makes it possible to reduce a voltage applied to the interface. Therefore, in conventional semiconductor laser devices, there is a case where the light guide layer 60 is undoped.

However, when the light guide layer 60 is undoped, the resistivity of the light guide layer 60 is increased. Thus, when the layer thickness of the light guide layer 60 is increased, the operating voltage is, on the contrary, increased. This results in a problem that the increase in the operating voltage causes the power consumption to be increased and the reliability to be deteriorated.

On the other hand, in the present embodiment, as described above, the effective acceptor concentration of the light guide layer 60 is set higher than the effective acceptor concentration of the clad layer 70, and hence such problem is not caused.

As described above, according to the present embodiment, the semiconductor laser device 1 includes: a crystal substrate (for example, the n-GaN substrate 10); a first clad layer of a first conductivity type formed on the crystal substrate (for example, the n-Al_{0.04}Ga_{0.96}N clad layer 20); a first light guide layer of the first conductivity type formed on the first clad layer (for example, the n-GaN light guide layer 30); an active layer of a single or multiple quantum well structure formed on the first light guide layer (for example, the MQW active layer 40); an overflow preventing layer of a second conductivity type formed on the active layer (for example, the p⁺-Al_{0.2}Ga_{0.8}N overflow preventing layer 50); a second light guide layer of the second conductivity type formed on the overflow preventing layer (for example, the p-GaN light guide layer 60); and a second clad layer of the second conductivity type formed on the second light guide layer (for example, the p-Al_{0.04}Ga_{0.96}N clad layer 70), wherein the carrier concentration (effective acceptor concentration) of the second light guide layer is set to the carrier concentration or more of the second clad layer. Thereby, it is possible to reduce the operating voltage.

Note that the effective acceptor concentration ratio, the acceptor concentration ratio, the carrier concentration ratio, and the impurity concentration ratio are substantially equal to each other. Therefore, even when the parts described as “effective acceptor concentration” in the above description are replaced by any of “acceptor concentration”, “carrier concentration”, and “impurity concentration”, respectively, the similar effects can be obtained.

Further, the active layer 40 is an InₓGa₁₋ₓN/In_{y}Ga_{1-y}N multiple quantum well active layer (0.05≦x≦1.0, 0≦y≦1.0, x>y). The overflow preventing layer 50 is formed of AlₜGa₁₋ₜN (t>0.15). The second light guide layer 60 is formed of GaN. The second clad layer 70 is formed of AlᵤGa₁₋ᵤN (0.0<u≦0.05). These materials are usually applicable to the nitride based semiconductor laser device 1 using the overflow preventing layer 50.

Further, the carrier concentration of the overflow preventing layer 50 is set to the carrier concentration or more of the second light guide layer 60. This makes it possible to improve the overflow preventing effect and thereby increase the carrier contributing to the radiative recombination. Thus, the optical output is increased.

Note that the above described embodiment is an example, and the present invention is not limited to the example. For example, it may also be constituted such that a p-type semiconductor is used as the crystal substrate, and that the p-type semiconductor is used as the p-side and the upper electrode is used as the n side.

Additional advantages and modifications will readily occur to those skilled in the art.

Therefore, the invention in its broader aspects is not limited to the specific details and representative embodiments shown and described herein.

Accordingly, various modifications may be made without departing from the spirit or scope of the general inventive concepts as defined by the appended claims and their equivalents.

What is claimed is:

1. A semiconductor laser device comprising:
a first clad layer of a first conductivity type;
a first light guide layer of the first conductivity type formed on the first clad layer;
an active layer of a single or multiple quantum well structure formed on the first light guide layer;
an overflow preventing layer of a second conductivity type formed on the active layer;
a second light guide layer of the second conductivity type formed on the overflow preventing layer; and
a second clad layer of the second conductivity type formed on the second light guide layer,
wherein the carrier concentration of the second light guide layer is set to the carrier concentration or more of the second clad layer.

2. The semiconductor laser device according to claim 1,
wherein the carrier concentration of the overflow preventing layer is set to the carrier concentration or more of the second light guide layer.

3. The semiconductor laser device according to claim 1,
wherein the active layer is an InₓGa₁₋ₓN/In_{y}Ga_{1-y}N multiple quantum well active layer (0.05≦x≦1.0, 0≦y≦1.0, x>y),
wherein the overflow preventing layer is formed of AlₜGa₁₋ₜN (t>0.15),
wherein the second light guide layer is formed of GaN, and
wherein the second clad layer is formed of AlᵤGa₁₋ᵤN (0.0<u≦0.05).

4. The semiconductor laser device according to claim 1, further comprising:
a diffusion preventing layer formed on the active layer, for preventing impurities from being diffused from the overflow preventing layer to the active layer.

5. The semiconductor laser device according to claim 1, further comprising:
a second contact layer of the second conductivity type formed on the second clad layer, the second clad layer and the second contact layer being processed and formed into a stripe-like ridge waveguide;
an insulating film formed on a surface other than an upper surface of the ridge waveguide;
a second electrode formed on the upper surface of the ridge waveguide;
a semiconductor substrate of the first conductivity type formed under the first clad layer; and
a first electrode formed on a lower surface of the semiconductor substrate.

6. The semiconductor laser device according to claim 1,
wherein the first conductivity type is an n-type, the second conductivity type is a p-type, and the carrier concentration is a hole concentration.

7. The semiconductor laser device according to claim 2,
wherein the active layer is an InₓGa₁₋ₓN/In_{y}Ga_{1-y}N multiple quantum well active layer (0.05≦x≦1.0, 0≦y≦1.0, x>y),
wherein the overflow preventing layer is formed of AlₜGa₁₋ₜN (t>0.15),
wherein the second light guide layer is formed of GaN, and
wherein the second clad layer is formed of AlᵤGa₁₋ᵤN (0.0<u≦0.05).

8. The semiconductor laser device according to claim 2, further comprising:
a diffusion preventing layer formed on the active layer, for preventing impurities from being diffused from the overflow preventing layer to the active layer.

9. The semiconductor laser device according to claim 2, further comprising:
a second contact layer of the second conductivity type formed on the second clad layer, the second clad layer and the second contact layer being processed and formed into a stripe-like ridge waveguide;
an insulating film formed on a surface other than an upper surface of the ridge waveguide;
a second electrode formed on the upper surface of the ridge waveguide;
a semiconductor substrate of the first conductivity type formed under the first clad layer; and
a first electrode formed on a lower surface of the semiconductor substrate.

10. The semiconductor laser device according to claim 2,
wherein the first conductivity type is an n-type, the second conductivity type is a p-type, and the carrier concentration is a hole concentration.

11. The semiconductor laser device according to claim 3, further comprising:
a diffusion preventing layer formed on the active layer, for preventing impurities from being diffused from the overflow preventing layer to the active layer.

12. The semiconductor laser device according to claim 7, further comprising:
a diffusion preventing layer formed on the active layer, for preventing impurities from being diffused from the overflow preventing layer to the active layer.

13. The semiconductor laser device according to claim 7, further comprising:
a second contact layer of the second conductivity type formed on the second clad layer, the second clad layer and the second contact layer being processed and formed into a stripe-like ridge waveguide;
an insulating film formed on a surface other than an upper surface of the ridge waveguide;
a second electrode formed on the upper surface of the ridge waveguide;
a semiconductor substrate of the first conductivity type formed under the first clad layer; and
a first electrode formed on a lower surface of the semiconductor substrate.

14. The semiconductor laser device according to claim 7,
wherein the first conductivity type is an n-type, the second conductivity type is a p-type, and the carrier concentration is a hole concentration.

15. A semiconductor laser device comprising:
a first clad layer of a first conductivity type;
a first light guide layer of the first conductivity type formed on the first clad layer;
an active layer of a single or multiple quantum well structure formed on the first light guide layer;
an overflow preventing layer of a second conductivity type formed on the active layer;
a second light guide layer of the second conductivity type formed on the overflow preventing layer; and
a second clad layer of the second conductivity type formed on the second light guide layer,
wherein the impurity concentration of the second light guide layer is set to the impurity concentration or more of the second clad layer.

16. The semiconductor laser device according to claim 15,
wherein the active layer is an InₓGa₁₋ₓN/In_{y}Ga_{1-y}N multiple quantum well active layer (0.05≦x≦1.0, 0≦y≦1.0, x>y),
wherein the overflow preventing layer is formed of AlₜGa₁₋ₜN (t>0.15),
wherein the second light guide layer is formed of GaN, and
wherein the second clad layer is formed of AlᵤGa₁₋ᵤN (0.0<u≦0.05).

17. The semiconductor laser device according to claim 15,
wherein the impurity concentration of the overflow preventing layer is set to the impurity concentration or more of the second light guide layer.

18. The semiconductor laser device according to claim 15, further comprising:
a diffusion preventing layer formed on the active layer, for preventing impurities from being diffused from the overflow preventing layer to the active layer.

19. The semiconductor laser device according to claim 15, further comprising:
a second contact layer of the second conductivity type formed on the second clad layer, the second clad layer and the second contact layer being processed and formed into a stripe-like ridge waveguide;
an insulating film formed on a surface other than an upper surface of the ridge waveguide;
a second electrode formed on the upper surface of the ridge waveguide;
a semiconductor substrate of the first conductivity type formed under the first clad layer; and
a first electrode formed on a lower surface of the semiconductor substrate.

20. The semiconductor laser device according to claim 15,
wherein the first conductivity type is an n-type, the second conductivity type is a p-type, and the impurity concentration is an effective acceptor concentration.
